(19) United States
(12) Patent Application Publication
(10) Pub. No.: US 2026/0324450 A1
(43) Pub. Date: Oct. 15, 2026

(54) METHOD FOR MANUFACTURING WIRING SUBSTRATE

(71) Applicant: IBIDEN CO., LTD., Gifu (JP)

(72) Inventors: Ramesh BHANDARI, Gifu (JP); Jun SAKAI, Gifu (JP)

(73) Assignee: IBIDEN CO., LTD., Gifu (JP)

(21) Appl. No.: 19/638,608

(22) Filed: Apr. 3, 2026

(30) Foreign Application Priority Data
Apr. 10, 2025 (JP) 2025-065266

(51) Int. Cl. H10W 70/05; B32B 38/00

(52) U.S. Cl. CPC H10W 70/096; B32B 38/0008; B32B 2307/202; B32B 2307/206; B32B 2457/08

(57) ABSTRACT

A method for manufacturing a wiring substrate includes forming a laminate having dividing lines, and dividing the laminate along the dividing lines such that the laminate is divided into wiring substrates. The forming the laminate includes forming a first metal layer at positions overlapping the dividing lines, forming a second metal layer at positions overlapping the dividing lines, forming a first build-up part, and forming a second build-up part, Metal material of each of the metal layers is different from material of conductor formed on exposed surfaces of the first and second parts, and the dividing the laminate includes forming a first groove along the diving lines such that the first groove penetrates the first part, forming a second groove along the dividing lines such that the second groove penetrates the second part, and cutting the laminate between the bottoms of the first and second grooves along the dividing lines.

### CROSS-REFERENCE TO RELATED APPLICATIONS

The present application is based upon and claims the benefit of priority to Japanese Patent Application No. 2025-065266, filed Apr. 10, 2025, the entire contents of which are incorporated herein by reference.

### BACKGROUND OF THE INVENTION

### Field of the Invention

The present invention relates to a method for manufacturing a wiring substrate.

### Description of Background Art

Japanese Patent Application Laid-Open Publication No. 2018-110150 describes a method for cutting a wiring substrate. The entire contents of this publication are incorporated herein by reference.

### SUMMARY OF THE INVENTION

According to one aspect of the present invention, a method for manufacturing a wiring substrate includes forming a laminate having dividing lines, and dividing the laminate along the dividing lines such that the laminate is divided into wiring substrates. The forming the laminate includes forming a first metal layer on a first surface of a core substrate at positions overlapping the dividing lines, forming a second metal layer on a second surface of the core substrate at positions overlapping the dividing lines, forming a first build-up part on the first surface of the core substrate, and forming a second build-up part on the second surface of the core substrate, the first and second metal layers in the laminate are formed such that a metal material of each of the first and second metal layers is different from a material of conductor formed on exposed surfaces of the first and second build-up parts, and the dividing the laminate includes forming a first groove along the diving lines such that the first groove penetrates the first build-up part from a surface of the first build-up part, forming a second groove along the dividing lines such that the second groove penetrates the second build-up part from a surface of the second build-up part, and cutting the laminate between a bottom of the first groove and a bottom of the second groove along the dividing lines.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view illustrating an example of a wiring substrate manufactured using a method for manufacturing a wiring substrate according to an embodiment of the present invention;

FIG. 2A is a cross-sectional view illustrating an example of a method for manufacturing a wiring substrate according to an embodiment of the present invention;

FIG. 2B is a cross-sectional view illustrating an example of a method for manufacturing a wiring substrate according to an embodiment of the present invention;

FIG. 2C is a cross-sectional view illustrating an example of a method for manufacturing a wiring substrate according to an embodiment of the present invention;

FIG. 2D is a cross-sectional view illustrating an example of a method for manufacturing a wiring substrate according to an embodiment of the present invention;

FIG. 3A is a cross-sectional view illustrating an example of a method for manufacturing a wiring substrate according to an embodiment of the present invention;

FIG. 3B is a cross-sectional view illustrating an example of a method for manufacturing a wiring substrate according to an embodiment of the present invention;

FIG. 3C is a cross-sectional view illustrating an example of a method for manufacturing a wiring substrate according to an embodiment of the present invention;

FIG. 3D is a cross-sectional view illustrating an example of a method for manufacturing a wiring substrate according to an embodiment of the present invention;

FIG. 4A is a cross-sectional view illustrating another example of a method for manufacturing a wiring substrate according to an embodiment of the present invention;

FIG. 4B is a cross-sectional view illustrating another example of a method for manufacturing a wiring substrate according to an embodiment of the present invention;

FIG. 5A is a cross-sectional view illustrating another example of a method for manufacturing a wiring substrate according to an embodiment of the present invention; and

FIG. 5B is a cross-sectional view illustrating another example of a method for manufacturing a wiring substrate according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

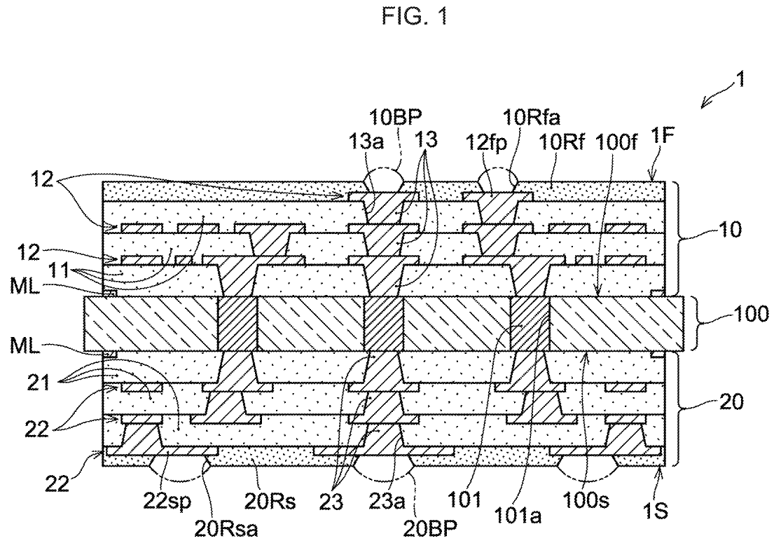

FIG. 1 illustrates a cross-sectional view of a wiring substrate 1, which is an example of a wiring substrate manufactured using a method for manufacturing a wiring substrate according an embodiment of the present invention. A laminated structure of a wiring substrate to be manufactured, as well as the respective numbers of conductor layers and insulating layers included in the wiring substrate, may differ from the laminated structure of the wiring substrate 1 illustrated in FIG. 1 and the respective numbers of conductor layers and insulating layers included in the wiring substrate 1.

The wiring substrate 1 is constituted by a core substrate 100 and build-up parts (10, 20) formed by alternately laminated insulating layers and conductor layers on both sides of the core substrate 100. The wiring substrate 1 has, as two main surfaces orthogonal to its thickness direction, a first surface (1F) and a second surface (1S) on an opposite side with respect to the first surface (1F).

The core substrate 100 included in the wiring substrate 1 has one surface (100f) and another surface (100s) on an opposite side with respect to the one surface (100f). On the one surface (100f) of the core substrate 100, first insulating layers 11 and first conductor layers 12 are alternately laminated to constitute the first build-up part 10. On the other surface (100s) of the core substrate 100, second insulating layers 21 and second conductor layers 22 are alternately laminated to constitute the second build-up part 20.

In describing a wiring substrate manufactured using the method for manufacturing a wiring substrate according to the embodiment, for each structural element of the wiring substrate 1, a side closer to the core substrate 100 is referred to as “lower” or “inner,” or “lower side” or “inner side,” and a side farther from the core substrate 100 is referred to as “upper” or “outer,” or “upper side” or “outer side.” For each element constituting the wiring substrate 1, a surface facing the core substrate 100 is also referred to as a “lower surface,” and a surface facing away from the core substrate 100 is also referred to as an “upper surface.”

In the core substrate 100, through conductors 101 penetrating the core substrate 100 in its thickness direction are formed. In each first insulating layer 11 constituting the first build-up part 10, first via conductors 13 are formed that penetrate the first insulating layer 11 in its thickness direction and connect conductors (between first conductor layers 12, or between a first conductor layer 12 and the through conductors 101) that face each other with the first insulating layer 11 interposed therebetween. In each second insulating layer 21 constituting the second build-up part 20, second via conductors 23 are formed that penetrate the second insulating layer 21 in its thickness direction and connect conductors (between second conductor layers 22, or between a second conductor layer 22 and the through conductors 101) that face each other with the second insulating layer 21 interposed therebetween.

The through conductors 101 are formed by filling through holes (101a) formed in the core substrate 100 with a conductive material. In the illustrated example, end surfaces of the through conductors 101 in their extending direction are formed substantially flush with the surfaces of the core substrate 100 and constitute the one surface (100f) and the other surface (100s) of the core substrate 100, respectively. The first via conductors 13 are formed by filling through holes (13a) formed in the first insulating layers 11 with a conductive material. Each first via conductor 13 is formed integrally with a first conductor layer 12 that is in contact with a surface of a first insulating layer 11 (that the first via conductor 13 penetrates) on an opposite side with respect to the core substrate 100. The second via conductors 23 are formed by filling through holes (23a) formed in the second insulating layers 21 with a conductive material. Each second via conductor 23 is formed integrally with a second conductor layer 22 that is in contact with a surface of a second insulating layer 21 (that the second via conductor 23 penetrates) on an opposite side with respect to the core substrate 100.

A core substrate included in a wiring substrate manufactured using the manufacturing method of the embodiment can be a glass substrate. The illustrated core substrate 100 of the wiring substrate 1 is formed using a glass substrate. As a glass material used for the glass substrate constituting the core substrate 100, for example, soda-lime glass, borosilicate glass, alkali-free glass, or the like can be used. These glasses may contain, as additives, elements such as magnesium, calcium, manganese, aluminum, lead, iron, chromium, potassium, sulfur, antimony, and boron. Further, the core substrate included in the wiring substrate may be a substrate containing a material other than glass, such as a silicon substrate, a ceramic substrate, or a resin substrate.

The first insulating layers 11 and the second insulating layers 21 are formed using any insulating resin. Examples of the insulating resin include: thermosetting resins such as epoxy resins, bismaleimide triazine resins (BT resins), or phenolic resins; and thermoplastic resins such as fluorine resins, liquid crystal polymers (LCP), fluoroethylene (PTFE) resins, polyester (PE) resins, and modified polyimide (MPI) resins. The first insulating layers 11 and the second insulating layers 21 can contain an inorganic filler (not illustrated) such as silica or alumina. The first insulating layers 11 and the second insulating layers 21 may also contain a reinforcing material (core material) such as glass fiber or aramid fiber.

Examples of conductive materials constituting the first conductor layers 12, the second conductor layers 22, the first via conductors 13, the second via conductors 23, and the through conductors 101 include copper, nickel, and the like, and copper is preferably used. In the example illustrated in FIG. 1, the first conductor layers 12, the second conductor layers 22, the first via conductors 13, the second via conductors 23, and the through conductors 101 are each illustrated as having a single-layer structure, but they can each have a multilayer structure. The first conductor layers 12, the second conductor layers 22, the first via conductors 13, the second via conductors 23, and the through conductors 101 can each have a multilayer structure that includes, for example, any of a metal foil layer (preferably copper foil), a metal film layer (preferably a copper film formed by electroless plating or sputtering), and a plating film layer (preferably an electrolytic copper plating film). For example, the first conductor layers 12, the second conductor layers 22, the first via conductors 13, the second via conductors 23, and the through conductors 101 can each have a two-layer structure including a metal film layer and a plating film layer.

The conductor layers (the first conductor layers 12 and the second conductor layers 22) constituting the wiring substrate 1 are each patterned to have predetermined conductor patterns. The first conductor layer 12 constituting the first surface (1F) of the wiring substrate 1 is formed to have patterns including multiple conductor pads (12fp). The second conductor layer 22 constituting the second surface (1S) of the wiring substrate 1 is formed to have patterns including multiple conductor pads (22sp).

The first build-up part 10 of the wiring substrate 1 includes, at its outermost side, a solder resist layer (10Rf) formed using, for example, a photosensitive polyimide resin or epoxy resin. Openings (10Rfa) are formed in the solder resist layer (10Rf), and the conductor pads (12fp) are exposed from the openings (10Rfa). That is, the first surface (1F) of the wiring substrate 1 includes a surface of the solder resist layer (10Rf) and surfaces of the conductor pads (12fp) exposed from the openings (10Rfa). The second build-up part 20 of the wiring substrate 1 includes, at its outermost side, a solder resist layer (20Rs) formed using, for example, a photosensitive polyimide resin or epoxy resin. Openings (20Rsa) are formed in the solder resist layer (20Rs), and the conductor pads (22sp) are exposed from the openings (20Rsa). That is, the second surface (1S) of the wiring substrate 1 includes a surface of the solder resist layer (20Rs) and surfaces of the conductor pads (22sp) exposed from the openings (20Rsa).

For example, a plating layer including a nickel layer and a tin layer, or the like, may be formed on the surfaces of the conductor pads (12fp) exposed from the openings (10Rfa) of the solder resist layer (10Rf) and the conductor pads (22sp) exposed from the openings (20Rsa) of the solder resist layer (20Rs), the conductor pads (12fp, 22sp) being formed of copper. Further, as illustrated, conductor bumps (10BP) connected to the conductor pads (12fp), indicated by two-dot chain lines in the drawing, may be formed in the openings (10Rfa) of the solder resist layer (10Rf). Conductor bumps (20BP) connected to the conductor pads (22sp), indicated by two-dot chain lines in the drawing, may be formed in the openings (20Rsa) of the solder resist layer (20Rs). The conductor bumps (10BP, 20BP) can be, for example, solder bumps containing tin, copper, or nickel. Therefore, when the wiring substrate 1 includes the conductor bumps (10BP, 20BP), conductors exposed on the first surface (1F) and second surface (1S) of the wiring substrate 1 can be, for example, copper, nickel, tin, or silver.

In the illustrated example, the first surface (1F) of the wiring substrate 1 is formed as a component mounting surface to which an external electronic component is connected, and the conductor pads (12fp) (or the conductor bumps (10BP) when formed) constituting the first surface (1F) can be connected to connection pads of the external electronic component when the wiring substrate 1 is in use. The second surface (1S) of the wiring substrate 1 can be a connecting surface to be connected to, for example, an external substrate such as a motherboard of any electrical device, when the wiring substrate 1 is mounted on the external substrate. When the wiring substrate 1 is in use, the conductor pads (22sp) (or the conductor bumps (20BP) when formed) constituting the second surface (1S) can be connected to connection pads on an external substrate.

As will be described in detail later, the single wiring substrate 1 in the illustrated example is formed by dividing a laminate including multiple wiring substrates 1 to singulate it into individual wiring substrates 1. Side surfaces extending in the thickness direction of the wiring substrate 1 are surfaces exposed by singulating the laminate into individual wiring substrates 1. In plan view, each individual wiring substrate 1 has a rectangular shape, and in the above-described laminate, the multiple wiring substrates 1 are connected in a lattice pattern. Here, the term “plan view” means viewing an object along the thickness direction of the wiring substrate 1.

As will be described in detail later, in a process of dividing a laminate, in which multiple wiring substrates 1 are connected, into individual wiring substrates 1, along dividing lines, a groove that penetrates the first build-up part 10 in the thickness direction and exposes, at its bottom, a metal layer on the one surface (100f) is formed, and a groove that penetrates the second build-up part 20 in the thickness direction and exposes, at its bottom, a metal layer on the other surface (100s) is formed. The metal layers exposed at the bottoms of the formed grooves are removed by etching, and the laminate between the one surface (100f) and the surface (100s) exposed by the removal of the metal layers is cut along the dividing lines. The metal layers are formed of a metal different from the conductors (the conductor pads (12fp, 22sp) or the conductor bumps (10BP, 20BP)) exposed on the surfaces of the laminate (that is, the surfaces of the wiring substrate 1). Therefore, in the etching for removing the metal layers, influence on the conductors exposed on the surfaces of the laminate is small. Therefore, the wiring substrate 1 is manufactured as a high-quality wiring substrate in which deterioration in quality of the surfaces of the exposed conductors is suppressed. In the drawing, metal portions (ML) that are located on the one surface (100f) and the other surface (100s) and are exposed at the side surfaces of the wiring substrate 1 are portions of the above-described metal layers that are not exposed at the bottoms of the grooves (that is, portions that are not removed by etching).

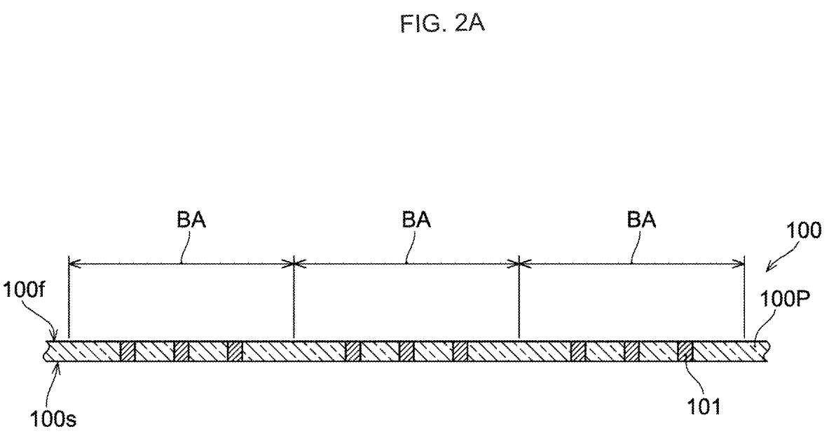

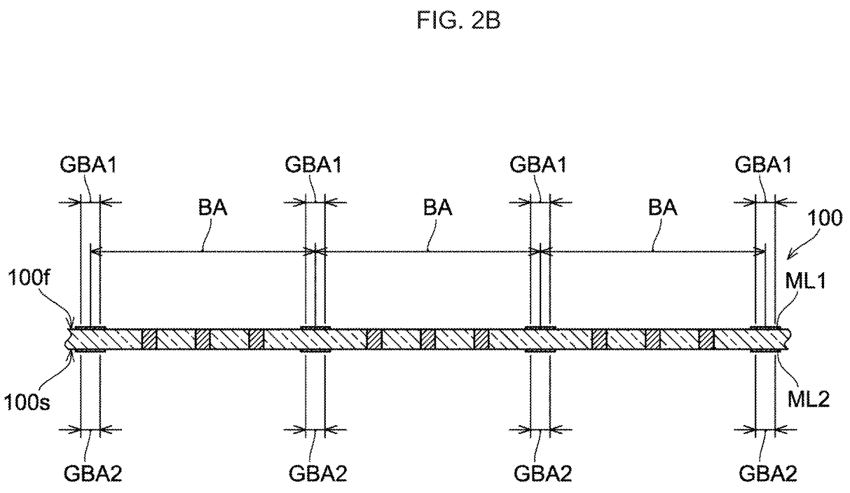

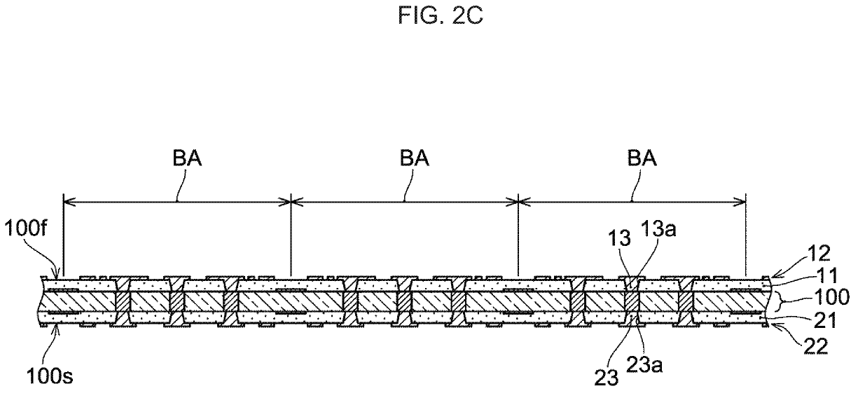

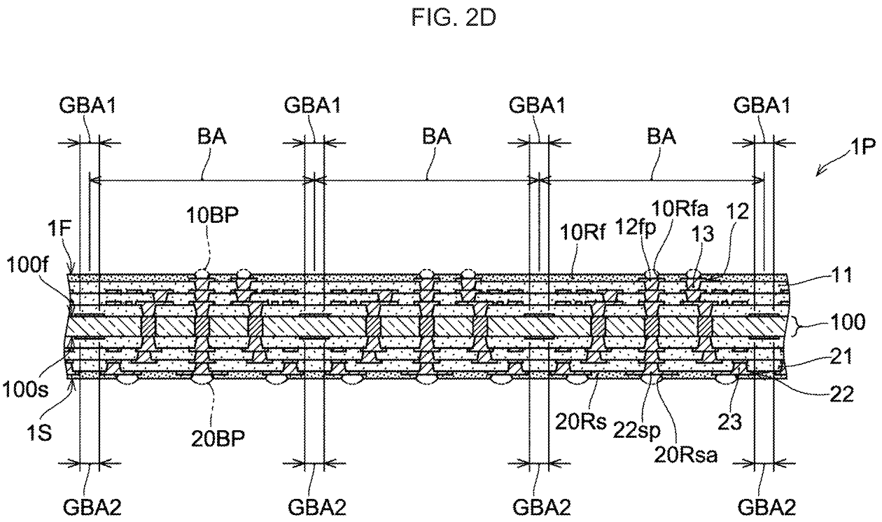

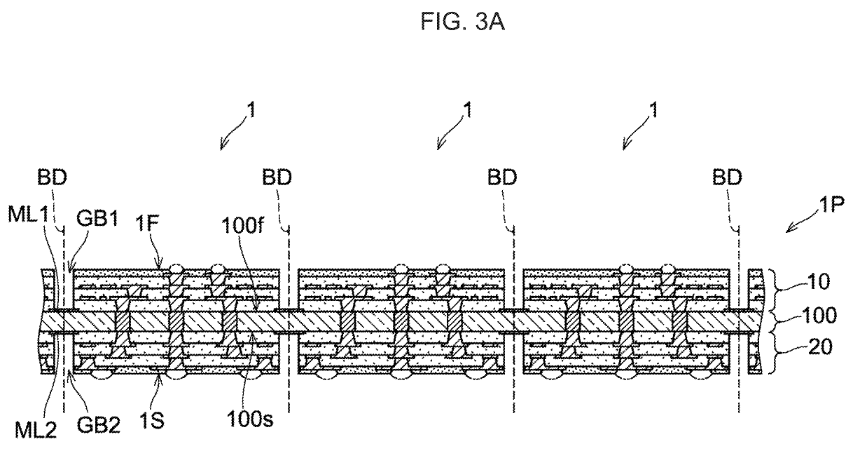

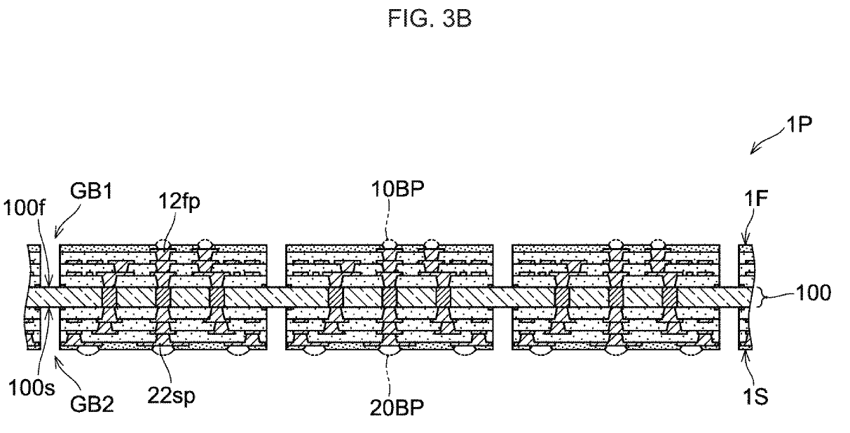

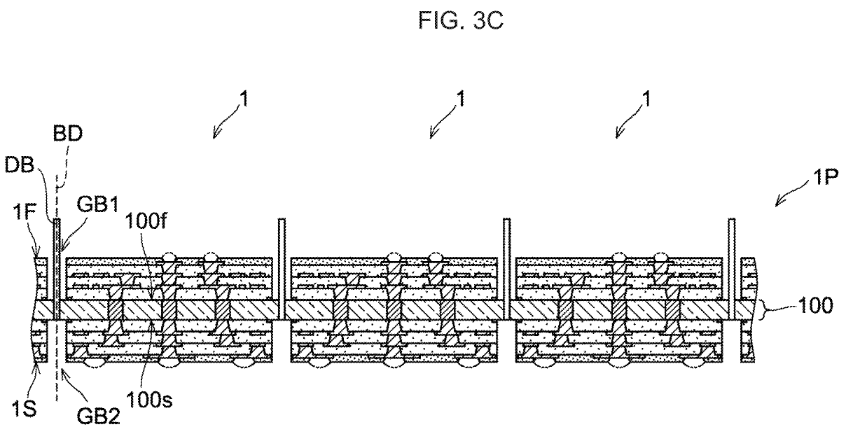

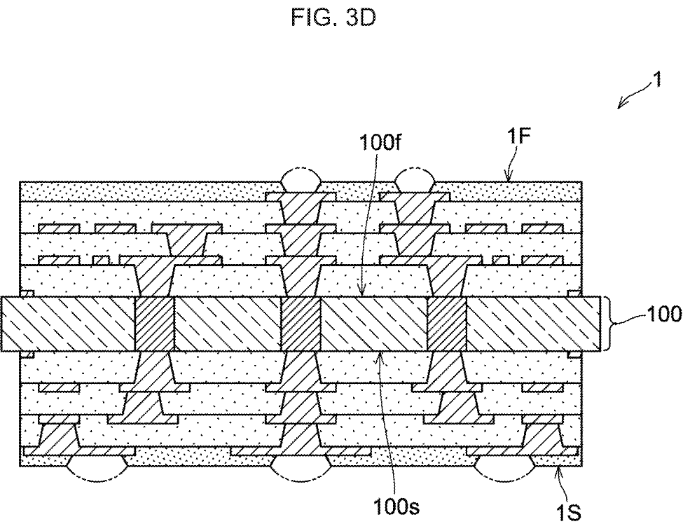

Next, with reference to FIGS. 2A to 2D, 3A to 3D, 4A and 4B, and 5A and 5B, a method for manufacturing a wiring substrate according to the embodiment is described. First, with reference to FIGS. 2A to 2D and 3A to 3D, an example of a case where the wiring substrate 1 illustrated in FIG. 1 is manufactured is described. Structural elements formed in the method for manufacturing a wiring substrate to be described below can be formed using the materials exemplified as the materials of the corresponding structural elements in the description of the wiring substrate 1 in FIG. 1, unless otherwise specified. Further, in FIGS. 2A to 5B to be referenced to below, the metal film layers and plating film layers that are structural elements of the conductor layers are not depicted, and each conductor layer is depicted as a single layer as in FIG. 1.

The method for manufacturing a wiring substrate according to the present embodiment includes: preparing a core substrate having a surface on one side and a surface on the other side; forming a first build-up part on the surface on one side; forming a second build-up part on the surface on the other side; and dividing a laminate including the core substrate, the first build-up part, and the second build-up part into multiple wiring substrates along dividing lines. Here, the term “laminate” refers to a state in which multiple wiring substrates to be singulated by division are connected together. First, formation of a laminate is described with reference to FIGS. 2A to 2D.

As illustrated in FIG. 2A, the core substrate 100 is prepared. For example, the core substrate 100 is prepared in which the through conductors 101 are formed in a glass substrate (100P) containing soda-lime glass, borosilicate glass, non-alkali glass, or the like.

The core substrate 100 includes multiple wiring substrate formation regions (BA) corresponding to connected multiple wiring substrates 1 to be manufactured. Although an example in which the core substrate 100 includes the glass substrate (100P) is illustrated, in the preparation of the core substrate 100, a silicon substrate, a ceramic substrate, or a resin substrate may be used as an alternative to the glass substrate (100P).

Next, as illustrated in FIG. 2B, a first metal layer (ML1) in contact with the one surface (100f) of the core substrate 100, and a second metal layer (ML2) in contact with the other surface (100s) of the core substrate 100 are formed. The first metal layer (ML1) and the second metal layer (ML2) are formed at positions overlapping, in plan view, with boundaries of the wiring substrate forming regions (BA) (that is, dividing lines (BD) in a process of dividing the laminate, which will be described later with reference to FIGS. 3A to 3D). The first metal layer (ML1) and the second metal layer (ML2) are formed over entire peripheral edges of the rectangular wiring substrate forming regions (BA) in plan view. The first metal layer (ML1) and the second metal layer (ML2) are formed of a metal material different from the conductors exposed on the surfaces (the first surface and the second surface) of the laminate at the time when a process to be described later with reference to FIG. 3B (removal of the first metal layer (ML1) and the second metal layer (ML2) by etching) is performed.

The formed first metal layer (ML1) and second metal layer (ML2) are formed as layers that do not contribute to transmission of electrical signals when a manufactured wiring substrate is in use and also do not function as a power supply layer or a ground layer. In the example described, on the one surface (100f) of the core substrate 100, the first conductor layers 12 constituting the first build-up part 10 are not formed, and no conductors other than the first metal layer (ML1) are formed. Further, on the other surface (100s), the second conductor layers 22 constituting the second build-up part 20 are not formed, and no conductors other than the second metal layer (ML2) are formed (see FIG. 1).

Specifically, the first metal layer (ML1) is formed on the one surface (100f) over a region corresponding to a region (GBA1) where a groove (GB1) is formed in a process of dividing the laminate, which will be described later with reference to FIG. 3A. The second metal layer (ML2) is formed on the other surface (100s) over a region corresponding to a region (GBA2) where a groove (GB2) is formed. The first metal layer (ML1) and the second metal layer (ML2) can be formed by forming a resist having openings on the surfaces of the core substrate 100, forming a metal layer in the openings by chemical vapor deposition (for example, CVD) or physical vapor deposition (for example, sputtering), and then removing the resist. The first metal layer (ML1) and the second metal layer (ML2) can be formed as, for example, a single layer of an aluminum layer or a titanium layer, or a multilayer including two or more different metal layers or alloy layers such as a titanium layer and a copper layer. The first metal layer (ML1) and the second metal layer (ML2) can be formed to have a thickness of, for example, 10 nm or more and 10 μm or less, and preferably 50 nm or more and 100 nm or less.

Next, as illustrated in FIG. 2C, a first insulating layer 11 that covers the one surface (100f) of the core substrate 100 is laminated, and further, the innermost first conductor layer 12 is formed on the first insulating layer 11. At the same time as the formation of the first conductor layer 12, the first via conductors 13 are integrally formed with the first conductor layer 12. The first insulating layer 11 is laminated over the multiple wiring substrate formation regions (BA), and the first conductor layer 12 and the first via conductors 13 are formed in the multiple wiring substrate formation regions (BA). A second insulating layer 21 that covers the other surface (100s) of the core substrate 100 is formed, and further, the innermost second conductor layer 22 is formed on the second insulating layer 21. At the same time as the formation of the second conductor layer 22, the second via conductors 23 are integrally formed with the second conductor layer 22. The second insulating layer 21 is laminated over the multiple wiring substrate formation regions (BA), and the second conductor layer 22 and the second via conductors 23 are formed in the multiple wiring substrate formation regions (BA).

In the example described, the first conductor layer 12 is not formed in contact with the one surface (100f), and the second conductor layer 22 is not formed in contact with the other surface (100s). Specifically, the innermost first conductor layer 12 is formed with the first insulating layer 11 interposed between the innermost first conductor layer 12 and the one surface (100f) (that is, spaced apart from the one surface (100f)), and the innermost second conductor layer 22 is formed with the second insulating layer 21 interposed between the innermost second conductor layer 22 and the other surface (100s) (that is, spaced apart from the other surface (100s)). The first conductor layer 12 can be formed to have a thickness greater than that of the first metal layer (ML1). The second conductor layer 22 can be formed to have a thickness greater than that of the second metal layer (ML2). The thickness of the formed first conductor layer 12 and second conductor layer 22 is, for example, 1 μm or more and 30 μm or less. Further, as described above, when the first conductor layer 12 and the second conductor layer 22 have a two-layer structure including a metal film layer and a plating film layer, the metal film layer can function as a power feeding layer for the plating film layer. In this case, the thickness of the power feeding layer (metal film layer) is, for example, 150 nm to 400 nm. The first metal layer (ML1) and the second metal layer (ML2) can be formed to have a thickness smaller than that of the metal film layer included in the first conductor layer 12 and that of the metal film layer included in the second conductor layer 22.

The first insulating layer 11 and the second insulating layer 21 can be formed by thermocompression bonding of a film-like insulating resin (for example, epoxy resin) onto the surfaces (the one surface (100f) and the other surface (100s)) of the core substrate 100. The through holes (13a) are formed, for example, by irradiation with CO₂ laser light at positions in the first insulating layer 11 where the first via conductors 13 are to be formed. The first conductor layer 12 and the first via conductors 13 are formed by forming a metal film layer (not illustrated) on inner surfaces of the through holes (13a) and on the upper surface of the first insulating layer 11 by electroless plating or sputtering, and then forming a plating film (not illustrated) by electrolytic plating using a plating resist having appropriate openings and using the metal film layer as a power feeding layer. The through holes (23a) are formed, for example, by irradiation with CO₂ laser light at positions in the second insulating layers 21 where the second via conductors 23 are to be formed. The second conductor layer 22 and the second via conductors 23 are formed by forming a metal film layer (not illustrated) on inner surfaces of the through holes (23a) and on the upper surface of the second insulating layer 21 by electroless plating or sputtering, and then forming a plating film (not illustrated) by electrolytic plating using a plating resist having appropriate openings and using the metal film layer as a power feeding layer.

Next, as illustrated in FIG. 2D, on the upper side of the one surface (100f) of the core substrate 100, processes similar to those described above for forming the first insulating layer 11 and integrally forming the first via conductors 13 and the first conductor layer 12 are repeated a desired number of times to form a desired number of first insulating layers 11 and first conductor layers 12. Further, on the upper side of the other surface (100s), processes similar to those described above for forming the second insulating layer 21 and integrally forming the second via conductors 23 and the second conductor layer 22 are repeated a desired number of times to form a desired number of second insulating layers 21 and second conductor layers 22. The outermost first conductor layer 12 is formed to have patterns including the conductor pads (12fp). The outermost second conductor layer 22 is formed to have patterns including the conductor pads (22sp). In the formation of the first conductor layers 12 and the second conductor layers 22, the patterns of the first conductor layers 12 are not formed in the region (GBA1) where the first groove (GB1) (see FIG. 3A) is to be formed, and the patterns of the second conductor layers 22 are not formed in the region (GBA2) where the second groove (GB2) (see FIG. 3A) is to be formed.

Further, the solder resist layer (10Rf) having the openings (10Rfa) that expose the conductor pads (12fp) is formed on the outermost first conductor layer 12 and first insulating layer 11 on the one surface (100f) side of the core substrate 100 over the multiple wiring substrate forming regions (BA). The formation of the first build-up part 10 having the first surface (1F), which is constituted by a surface of the solder resist layer (10Rf) on an opposite side with respect to the one surface (100f) of the core substrate 100 and the upper surfaces of the conductor pads (12fp), is completed. The solder resist layer (20Rs) having the openings (20Rsa) that expose the conductor pads (22sp) is formed on the outermost second conductor layer 22 and second insulating layer 21 on the other surface (100s) side of the core substrate 100 over the multiple wiring substrate forming regions (BA). The formation of the second build-up part 20 having the second surface (1S), which is constituted by a surface of the solder resist layer (20Rs) on an opposite side with respect to the other surface (100s) of the core substrate 100 and the upper surfaces of the conductor pads (22sp), is completed.

Through the processes described above with reference to FIGS. 2A to 2D, the formation of a laminate (1P) in a state in which the multiple wiring substrates 1 are connected is completed. In the formed laminate (1P), the conductive bumps (10BP, 20BP) indicated by two-dot chain lines in the drawing may be formed as conductive connecting elements on the conductor pads (12fp, 22sp). The conductor bumps (10BP, 20BP) can be formed, for example, by printing and reflowing a tin-copper solder paste onto the conductor pads (12fp, 22sp).

Next, with reference to FIGS. 3A to 3D, a process of dividing the formed laminate (1P) to singulate it into individual wiring substrates 1 is described. In the method for manufacturing a wiring substrate according to the embodiment, dividing the laminate includes: forming a first groove (GB1) that penetrates the first build-up part 10 in the thickness direction from the first surface (1F) and forming a second groove (GB2) that penetrates the second build-up part 20 in the thickness direction from the second surface (1S); and cutting along dividing lines (BD) between a bottom of the first groove (GB1) and a bottom of the second groove (GB2).

First, as illustrated in FIG. 3A, along the dividing lines (BD) that are the boundaries between the multiple wiring substrates 1 constituting the laminate (1P), the first groove (GB1) penetrating the first build-up part 10 in the thickness direction and the second groove (GB2) penetrating the second build-up part 20 in the thickness direction are formed. The first groove (GB1) can be formed, for example, by irradiating laser light such as CO₂ laser light from an outer side of the first build-up part 10 toward the laminate (1P). The second groove (GB2) can be formed, for example, by irradiating laser light such as CO₂ laser light from an outer side of the second build-up part 20 toward the laminate (1P). The first groove (GB1) and the second groove (GB2) may also be formed using a dicing blade that may be used in general dicing.

The first groove (GB1) and the second groove (GB2) can be formed over entire rectangular peripheral edges of the wiring substrates 1 in plan view. When the first groove (GB1) and the second groove (GB2) are formed using laser light, the first metal layer (ML1) and the second metal layer (ML2) function as stopper layers for the laser light. In the illustrated example, the first groove (GB1) penetrates the innermost first insulating layer 11 of the first build-up part 10 and exposes the first metal layer (ML1) at its bottom. The second groove (GB2) penetrates the innermost second insulating layer 21 of the second build-up part 20 and exposes the second metal layer (ML2) at its bottom.

Next, the first metal layer (ML1) exposed at the bottom of the first groove (GB1) is removed by etching, and the second metal layer (ML2) exposed at the bottom of the second groove (GB2) is removed by etching. In the process of removing the first metal layer (ML1) and the second metal layer (ML2) by etching, a chemical solution suitable for removing the metal material constituting the first metal layer (ML1) and the second metal layer (ML2) is used. The first metal layer (ML1) and the second metal layer (ML2) are made of a material different from the metal material constituting the conductors exposed on the surfaces of the laminate (1P) (the metal material constituting the upper surfaces of the conductor pads (12fp, 22sp), or the metal material constituting the conductor bumps (10BP, 20BP)). Accordingly, a degree of influence of the etching on the surfaces of the conductors exposed on the first surface (1F) and the second surface (1S) of the laminate (1P) is suppressed. As illustrated in FIG. 3B, by removing the first metal layer (ML1), the one surface (100f) of the core substrate 100 is exposed at the bottom of the first groove (GB1). By removing the second metal layer (ML2), the surface (100s) of the core substrate 100 is exposed at the bottom of the second groove (GB2).

Next, as illustrated in FIG. 3C, the laminate between the bottom of the first groove (GB1) and the bottom of the second groove (GB2) is cut along the dividing lines (BD). For example, as illustrated, by completely cutting the core substrate 100 with a dicing blade (DB), the connected multiple wiring substrates 1 are completely separated and singulated into individual wiring substrates 1. In cutting the core substrate 100, cleaving of the core substrate 100 by scribing using an appropriate scribing device may be performed, or a method of applying an external force to cut the core substrate 100 after forming modified regions or cracks (micro-cracks) in the core substrate 100 using a laser may be employed. As illustrated in FIG. 3D, the manufacture of the singulated wiring substrate 1 is completed. As described above, in the process described with reference to FIG. 3B, the degree of influence of the etching on the surfaces of the conductors exposed on the surfaces of the laminate (1P) is kept small, and therefore, the conductors exposed on the first surface (1F) and the second surface (1S) of the manufactured wiring substrate 1 have high-quality surfaces.

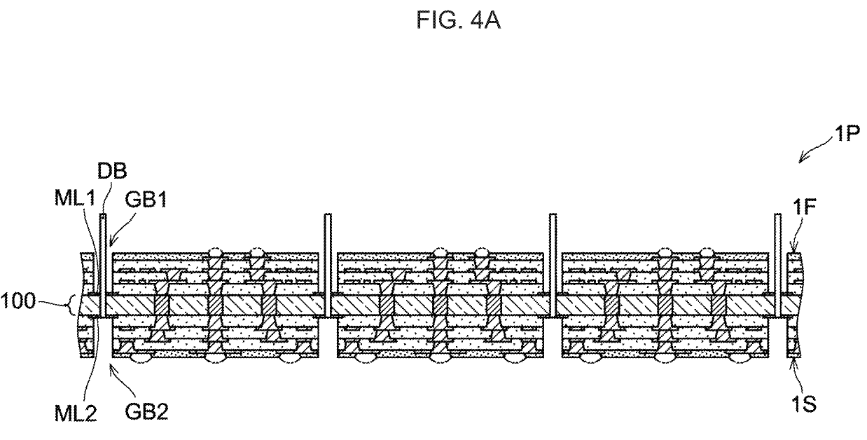

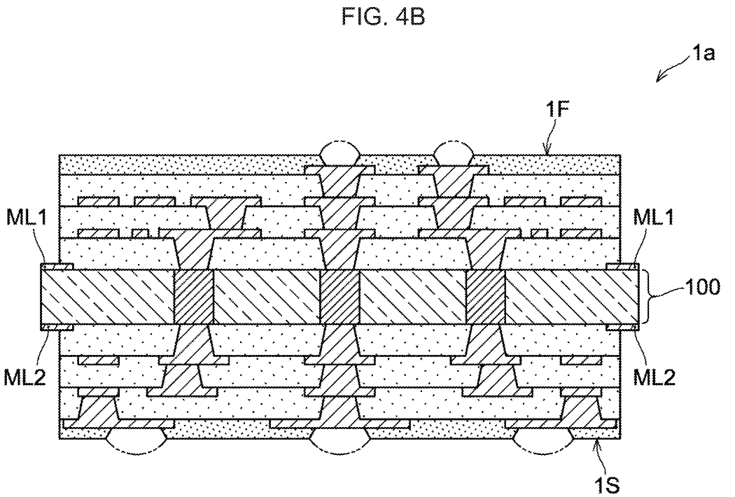

As another example of the process of singulating the laminate into individual wiring substrates, which differs from the example described with reference to FIGS. 3A to 3D, it is also possible that the removal of the first metal layer (ML1) and the second metal layer (ML2) described with reference to FIG. 3B is not performed. In this case, as illustrated in FIG. 4A, the first metal layer (ML1), the core substrate 100, and the second metal layer (ML2) are collectively cut using a dicing blade (DB) or by scribing. In cutting the first metal layer (ML1) and the second metal layer (ML2) using a dicing blade (DB), cutting debris of the metal material constituting the first metal layer (ML1) and the second metal layer (ML2) is generated. The cutting debris can be removed from the surfaces of the laminate (1P) by cleaning. However, when conductors made of the same metal material as the cutting debris are exposed on the surfaces of the laminate (1P), the cutting debris may adhere firmly to the surfaces of the conductors and may not be easily removed. In the method for manufacturing a wiring substrate according to the embodiment, since the first metal layer (ML1) and the second metal layer (ML2) are formed of a metal material different from the conductors exposed on the first surface (1F) and the second surface (1S), it is thought that such firm adhesion of the cutting debris to the surfaces of the conductors is suppressed and the cutting debris can be easily removed. As a result of the process illustrated in FIG. 4A, as illustrated in FIG. 4B, a singulated wiring substrate (1a) is obtained in which the upper surfaces of the first metal layer (ML1) and the second metal layer (ML2) are exposed.

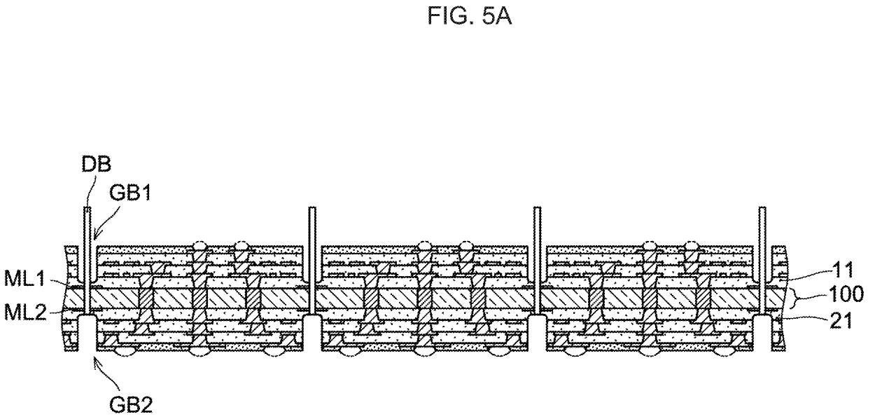

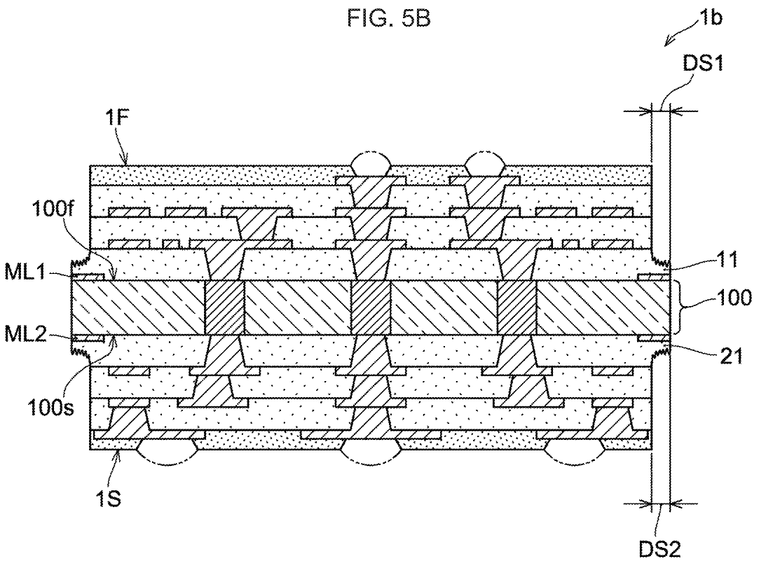

Further, as yet another example different from the example described with reference to FIGS. 3A to 3D, in the process described with reference to FIG. 3A, the first groove (GB1) may be formed as a groove penetrating to a position on an outer side of the first metal layer (ML1), and the second groove (GB2) may be formed as a groove penetrating to a position on an outer side of the second metal layer (ML2). In this case, the bottom of the first groove (GB1) is constituted by the first insulating layer 11, and the bottom of the second groove (GB2) is constituted by the second insulating layer 21, and as illustrated in FIG. 5A, the first insulating layer 11, the first metal layer (ML1), the core substrate 100, the second metal layer (ML2), and the second insulating layer 21 are collectively cut using a dicing blade (DB). Also in this case, the firm adhesion of the cutting debris of the first metal layer (ML1) and the second metal layer (ML2), as described above, to the surfaces of the conductors exposed on the surfaces of the laminate (1P) is suppressed.

As illustrated, when the bottom of the first groove (GB1) is constituted by the first insulating layer 11, the surface of the first insulating layer 11 exposed at the bottom after the first groove (GB1) is formed can become a roughened surface. When the bottom of the second groove (GB2) is constituted by the second insulating layer 21, the surface of the second insulating layer 21 exposed at the bottom after the second groove (GB2) is formed can become a roughened surface. In this case, the surface of the first insulating layer 11 constituting the bottom of the first groove (GB1) and the surface of the second insulating layer 21 constituting the bottom of the second groove (GB2) can be formed as surfaces having a roughness of, for example, 0.5 μm or more and 5 μm or less in terms of arithmetic mean roughness (Ra).

As a result of the process illustrated in FIG. 5A, as illustrated in FIG. 5B, a singulated wiring substrate (1b) is obtained in which the upper surfaces of the first insulating layer 11 and the second insulating layer 21 that are roughened near the side surfaces are exposed. Since the roughened upper surfaces of the first insulating layer 11 and the second insulating layer 21 are exposed near the side surfaces, excessive wetting and spreading of underfill is suppressed when applying underfill during mounting of an external electronic component in the use of the wiring substrate (1b).

From a viewpoint of suppressing an increase in size of the wiring substrate (1, 1a, 1b), in plan view, a shortest distance (DS1) between a side surface of the core substrate 100 constituting an peripheral edge of the wiring substrate (1, 1a, 1b) and a side surface of the first build-up part 10, and a shortest distance (DS2) between the side surface of the core substrate 100 and a side surface of the second build-up part 20, are each preferably 60 μm or less.

Japanese Patent Application Laid-Open Publication No. 2018-110150 describes a method for cutting a wiring substrate in which wiring layers and insulating layers are laminated on both surfaces (two core surfaces) of a core substrate to singulate it into individual package substrates. In the method, separation grooves are formed by removing portions of the insulating layers by laser irradiation, and the core substrate is cut from bottoms of the separation grooves using a dicing blade. Wiring layers are formed in contact with both surfaces of the core substrate, and outer peripheral patterns containing the same material as the wiring layers are formed at positions corresponding to the positions where the separation grooves are formed on both surfaces of the core substrate.

In the method described in Japanese Patent Application Laid-Open Publication No. 2018-110150, the outer peripheral patterns exposed at the bottoms of the formed separation grooves is dissolved and removed by etching. In the method, the wiring layers and the outer peripheral patterns contain the same material (copper), and when the outer peripheral patterns are dissolved and removed, the wiring layers exposed on the outermost surfaces of the wiring substrate may be affected by the etching, and there is a risk that the quality of the surfaces of the outermost wiring layers may deteriorate.

A method for manufacturing a wiring substrate according to an embodiment of the present invention include: preparing a core substrate having one surface and another surface on an opposite side with respect to the one surface; forming, on the one surface, a first build-up part including a first insulating layer and a first conductor layer and having a first surface on an opposite side with respect to the core substrate; forming, on the other surface, a second build-up part including a second insulating layer and a second conductor layer and having a second surface on an opposite side with respect to the core substrate; and dividing a laminate including the core substrate, the first build-up part, and the second build-up part into multiple wiring substrates along dividing lines. The method further includes forming, at positions overlapping with the dividing lines in plan view, a first metal layer in contact with the one surface and a second metal layer in contact with the other surface. The dividing of the laminate includes: forming a first groove penetrating the first build-up part from the first surface; forming a second groove penetrating the second build-up part from the second surface; and cutting the laminate along the dividing lines between a bottom of the first groove and a bottom of the second groove,. The first metal layer and the second metal layer are formed of a metal different from a material of a conductor exposed on the first surface and a conductor exposed on the second surface.

According to an embodiment of the present invention, the first metal layer and the second metal layer are formed of a metal different from the material of the conductor exposed on the first surface and the conductor exposed on the second surface of the wiring substrate, and therefore, deterioration in quality of the surfaces of the conductors exposed on the first surface and the second surface can be suppressed.

Obviously, numerous modifications and variations of the present invention are possible in light of the above teachings. It is therefore to be understood that within the scope of the appended claims, the invention may be practiced otherwise than as specifically described herein.

1. A method for manufacturing a wiring substrate, comprising:
forming a laminate having a plurality of dividing lines; and
dividing the laminate along the plurality of dividing lines such that the laminate is divided into a plurality of wiring substrates,
wherein the forming the laminate includes forming a first metal layer on a first surface of a core substrate at positions overlapping the plurality of dividing lines, forming a second metal layer on a second surface of the core substrate at positions overlapping the plurality of dividing lines, forming a first build-up part on the first surface of the core substrate, and forming a second build-up part on the second surface of the core substrate, the first and second metal layers in the laminate are formed such that a metal material of each of the first and second metal layers is different from a material of conductor formed on exposed surfaces of the first and second build-up parts, and the dividing the laminate includes forming a first groove along the diving lines such that the first groove penetrates the first build-up part from a surface of the first build-up part, forming a second groove along the dividing lines such that the second groove penetrates the second build-up part from a surface of the second build-up part, and cutting the laminate between a bottom of the first groove and a bottom of the second groove along the plurality of dividing lines.

2. The method for manufacturing a wiring substrate according to claim 1, wherein the forming the first build-up part includes forming an innermost first conductor layer spaced apart from the first surface of the core substrate, and the forming the second build-up part includes forming an innermost second conductor layer spaced apart from the second surface of the core substrate.

3. The method for manufacturing a wiring substrate according to claim 1, wherein the forming the first groove includes exposing the first metal layer at a bottom of the first groove, and the forming the second groove includes exposing the second metal layer at a bottom of the second groove.

4. The method for manufacturing a wiring substrate according to claim 3, wherein
the forming the first groove includes removing the first metal layer such that the first surface of the core substrate is exposed at a bottom of the first groove, and the forming the second groove includes removing the second metal layer such that the second surface of the core substrate is exposed at a bottom of the second groove.

5. The method for manufacturing a wiring substrate according to claim 1, wherein
the first build-up part comprises a first insulating layer, the forming the first groove includes exposing the first insulating layer at a bottom of the first groove, the second build-up part comprises a second insulating layer, and the forming the second groove includes exposing the second insulating layer at a bottom of the second groove.

6. The method for manufacturing a wiring substrate according to claim 5, wherein
the forming the first groove includes exposing the first insulating layer such that an exposed surface of the first insulating layer at the bottom of the first groove has an arithmetic mean roughness of 0.5 μm or more, and the forming the second groove includes exposing the second insulating layer such that an exposed surface of the second insulating layer at the bottom of the second groove has an arithmetic mean roughness of 0.5 μm or more.

7. The method for manufacturing a wiring substrate according to claim 5, wherein the laminate is cut such that a shortest distance between a side surface of the first groove and a side surface of the core substrate formed by the cutting is 60 μm or less and that a shortest distance between a side surface of the second groove and the side surface of the core substrate formed by the cutting is 60 μm or less.

8. The method for manufacturing a wiring substrate according to claim 1, wherein
the first build-up part includes a first conductor layer such that the first metal layer is formed to have a thickness smaller than a thickness of the first conductor layer, and the second build-up part is formed such that the second metal layer is formed to have a thickness smaller than a thickness of the second conductor layer.

9. The method for manufacturing a wiring substrate according to claim 1, wherein the first build-up part is formed such that the first metal layer has a thickness in a range of 50 nm to 100 nm, and the second build-up part is formed such that the second metal layer has a thickness in a range of 50 nm to 100 nm.

10. The method for manufacturing a wiring substrate according to claim 1, wherein the conductor formed on the exposed surfaces of the first and second build-up parts includes a plurality of conductive connecting elements.

11. The method for manufacturing a wiring substrate according to claim 1, wherein the core substrate includes a glass substrate.

12. The method for manufacturing a wiring substrate according to claim 2, wherein the forming the first groove includes exposing the first metal layer at a bottom of the first groove, and the forming the second groove includes exposing the second metal layer at a bottom of the second groove.

13. The method for manufacturing a wiring substrate according to claim 12, wherein the forming the first groove includes removing the first metal layer such that the first surface of the core substrate is exposed at a bottom of the first groove, and the forming the second groove includes removing the second metal layer such that the second surface of the core substrate is exposed at a bottom of the second groove.

14. The method for manufacturing a wiring substrate according to claim 2, wherein the first build-up part comprises a first insulating layer, the forming the first groove includes exposing the first insulating layer at a bottom of the first groove, the second build-up part comprises a second insulating layer, and the forming the second groove includes exposing the second insulating layer at a bottom of the second groove.

15. The method for manufacturing a wiring substrate according to claim 14, wherein the forming the first groove includes exposing the first insulating layer such that an exposed surface of the first insulating layer at the bottom of the first groove has an arithmetic mean roughness of 0.5 μm or more, and the forming the second groove includes exposing the second insulating layer such that an exposed surface of the second insulating layer at the bottom of the second groove has an arithmetic mean roughness of 0.5 μm or more.

16. The method for manufacturing a wiring substrate according to claim 14, wherein the laminate is cut such that a shortest distance between a side surface of the first groove and a side surface of the core substrate formed by the cutting is 60 μm or less and that a shortest distance between a side surface of the second groove and the side surface of the core substrate formed by the cutting is 60 μm or less.

17. The method for manufacturing a wiring substrate according to claim 2, wherein the first build-up part includes a first conductor layer such that the first metal layer is formed to have a thickness smaller than a thickness of the first conductor layer, and the second build-up part is formed such that the second metal layer is formed to have a thickness smaller than a thickness of the second conductor layer.

18. The method for manufacturing a wiring substrate according to claim 2, wherein the first build-up part is formed such that the first metal layer has a thickness in a range of 50 nm to 100 nm, and the second build-up part is formed such that the second metal layer has a thickness in a range of 50 nm to 100 nm.

19. The method for manufacturing a wiring substrate according to claim 2, wherein the conductor formed on the exposed surfaces of the first and second build-up parts includes a plurality of conductive connecting elements.

20. The method for manufacturing a wiring substrate according to claim 2, wherein the core substrate includes a glass substrate.
